(19) United States
(12) Patent Application Publication
(10) Pub. No.: US 2026/0354043 A1
(43) Pub. Date: Nov. 5, 2026

(54) MEMRISTIVE TRANSISTOR STRUCTURE, ELECTRONIC CIRCUIT, AND METHODS THEREOF

(71) Applicant: TechIFab GmbH, Radeberg (DE)

(72) Inventors: Sahitya Varma Vegesna, Jena (DE); Heidemarie Krüger, Dresden (DE); Ernst Bretschneider, Erfurt (DE); Maciej Wiatr, Dresden (DE); Martin Kidszun, Dresden (DE)

(21) Appl. No.: 19/557,894

(22) Filed: Mar. 5, 2026

(30) Foreign Application Priority Data
Mar. 6, 2025 (DE) 10 2025 108 558.7

(51) Int. Cl. H10N 70/20; G11C 13/00

(52) U.S. Cl. CPC H10N 70/253; G11C 13/0007; H10N 70/24; G11C 2213/53

(57) ABSTRACT

According to various aspects, a memristive transistor structure may include a channel portion including a semiconductive memristive material in a predefined memristive operation state. The memristive transistor structure may further include at least two source/drain electrodes associated with the channel portion and configured to provide an electric current path between the at least two source/drain electrodes through the channel portion. The memristive transistor structure may further include one or more gate electrodes associated with the channel portion and configured to change an electronic behavior of the channel portion.

### CROSS REFERENCE TO RELATED APPLICATION

This Patent Application claims priority from German Patent Application No. 10 2025 108 558.7 filed on Mar. 6, 2025 according to 35 U.S.C. § 119, the entire disclosure of which is incorporated herein by reference and in its entirety.

### TECHNICAL FIELD

Various aspects relate to a memristive transistor structure, an electronic circuit including one or more memristive transistor structures, and methods thereof, e.g., methods for operating a memristive transistor structure and/or an electronic device.

### BACKGROUND

In general, various data processing applications may rely on transistor technologies. However, it was found that resistor arrays may be useful for some data processing applications as well. Such resistor-based technologies were further developed to allow for a selective reconfiguration of an electric resistance of resistors. Such devices having a non-volatile, reconfigurable electric resistance may be referred to as memristive devices or memristors, for example. Memristor crossbar arrays were developed to replace transistors and memory cells in some data processing and data storage applications. However, an occurrence of leakage currents in memristor based crossbar arrays may limit a scalability of such structures. Therefore, several types of memristors with nonlinear resistance behavior have been proposed to reduce leakage currents when reconfiguring and reading selective memristors over nonselective memristors. These include so-called complementary resistance switches, which include two memristive structures connected in series, wherein a disadvantage of this technology may be that the state of the complementary resistance can be only read out destructively and, therefore, the complementary resistance switch has to be rewritten after readout. An approach for a nondestructive readout of a state of a complementary resistive switch may be based on capacitance measurements. A complementary resistive switch may include a two-layer memristive structure with strong nonlinear resistive behavior and a single-layer memristive structure with strong nonlinear resistive behavior.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 schematically shows various aspects of a memristive transistor structure;

FIG. 2 schematically shows various aspects of a control of a memristive transistor structure;

FIG. 3A to FIG. 3G schematically show various aspects of a memristive transistor structure;

FIG. 4A to FIG. 4D schematically show various aspects of a memristive transistor structure;

FIG. 5 schematically shows various aspects of a method for operating a memristive transistor structure;

FIG. 6A to FIG. 6C schematically show various aspects of a memristive transistor structure;

FIG. 7A to FIG. 7F schematically show various aspects of a memristive transistor structure;

FIG. 8A and FIG. 8B schematically show various aspects of a memristive transistor structure;

FIG. 9 schematically shows various aspects of a memristive circuit that includes one or more memristive transistor structures;

FIG. 10A and FIG. 10B schematically show various aspects of an inverter circuit that includes one or more memristive transistor structures; and

FIG. 11A and FIG. 11B schematically show various aspects of a logic circuit that includes one or more memristive transistor structures.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects can be combined with one or more other aspects to form new aspects. Various aspects are described in connection with methods and various aspects are described in connection with devices (e.g., arrangements). However, it may be understood that aspects described in connection with methods may similarly apply to the devices, and vice versa.

The terms “at least one” and “one or more” may be understood to include any integer number greater than or equal to one, i.e., one, two, three, four, [ . . . ], etc. The term “a plurality” may be understood to include any integer number greater than or equal to two, i.e., two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

The term “coupled” may be used herein with respect to nodes, circuit elements, and the like, to mean a, e.g. direct or indirect, connection and/or interaction. Several elements may, for example, be coupled together along an interaction chain (e.g., an electrically conductive path), along which the interaction (e.g., electrical charges) may be transmitted. For example, two elements coupled together may interact with each other.

The term “connected” or “connection” may be used herein with respect to nodes, circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected.”

In some aspects, two physical and/or chemical properties (e.g., an electrical voltage, an electrical current, an electrical conductance, a thickness, an electrical conductivity, a doping concentration, as examples) may be compared with one another by relative terms such as “greater”, “higher”, “lower”, “less”, or “equal”, for example. It is understood that, in some aspects, a comparison may include a sign (positive or negative) of a value representing the physical and/or chemical properties or, in other aspects, the absolute values are considered for the comparison. However, a comparison of measurement values representing a physical and/or chemical property may usually include a measurement of such measurement values by the same measurement principle or at least by comparable measurement principles.

Transistor technology is at the core of modern electronics, driving advancements in computing, communication, and various other fields. FinFETs, or Fin-Field-Effect Transistors, represent a significant evolution from traditional planar transistors. Their 3D-structure, characterized by a thin “fin” that rises above the substrate, allows for better control over the channel. This design offers improved performance, reduced leakage current, and enhanced scalability, making FinFETs suitable for advanced semiconductor nodes. Gate-All-Around (GAA) transistors take the concept of 3D control further by wrapping the gate around the channel on all sides. This design provides superior electrostatic control compared to FinFETs, resulting in enhanced performance and scalability, particularly for nodes below 5 nm. GAA transistors are positioned as a key technology for future semiconductor devices. Wide-bandgap semiconductors, such as Gallium Nitride (GaN) and Silicon Carbide (SiC), are gaining traction due to their superior properties compared to silicon. These materials offer higher efficiency, better thermal performance, and are well-suited for high-power and high-frequency applications. The trend of miniaturizing transistors continues to be a driving force in the semiconductor industry. By scaling down transistor sizes, manufacturers can fit more transistors on a chip, enhancing processing power and efficiency. However, as transistors approach atomic scales, managing heat dissipation and quantum effects becomes increasingly challenging.

Researchers are exploring materials beyond silicon, such as graphene and other 2D materials, to overcome the limitations of traditional silicon transistors. These materials offer ultra-thin profiles and high conductivity, which could revolutionize future electronics. Innovations in semiconductor manufacturing, including extreme ultraviolet (EUV) lithography, are critical for producing smaller and more efficient chips. These processes are essential for maintaining the pace of Moore's Law and meeting the demands of modern computing. The integration of transistors with emerging technologies such as artificial intelligence (AI), the Internet of Things (IoT), and 5G is driving the development of smarter and more connected devices. This integration leads to the creation of more powerful and energy-efficient electronics, enabling new applications and services. The advancements in transistor technology and the ongoing trends are pushing the boundaries of what is possible with semiconductor devices. As researchers and engineers continue to innovate, the future of electronics looks promising, with potential breakthroughs that could transform various industries.

Various aspects described herein relate to a new type of transistor having the capability of being configurable with respect to electronic properties such as current/voltage(I/V)-behavior. The transistor as described herein is based on a channel design using a memristive semiconductor material. The memristive semiconductor material allows for an electronic reconfiguration of the size and the shape of the depletion area in the channel and therefore to define the electronic properties of the transistor. The memristive semiconductor material allows for an electronic reconfiguration of one or more Schottky-Barriers with electrodes being in contact with the channel and therefore to define the electronic properties of the transistor. The reconfiguration is based, in some aspects, based on controlling and defining a charge carrier (ion or ion-vacancy) distribution in the channel by applying a respective electric field via one or more electrodes. The applied electric field is used to write the memristive material into a predefined state (e.g., by relocation of the charge carrier, e.g., by causing a drift of the charge carrier). The memristive material may include traps (e.g., induced by additional dopants or material defects) to allow for a non-volatile reconfiguration. In this case, the charge carrier can be relocated by the applied electric field but are trapped at there positions and the charge carrier distribution remains constant as long as no other applied electric field is present that cause a relocation again. The trapping of the charge carrier may be used to bring the memristive material into a predefined state by an electric write field (referred to as writing, write operation, or configuration operation) and to operate the transistor with the memristive material without modifying the predefined state (referred to as reading, read operation, transistor operation).

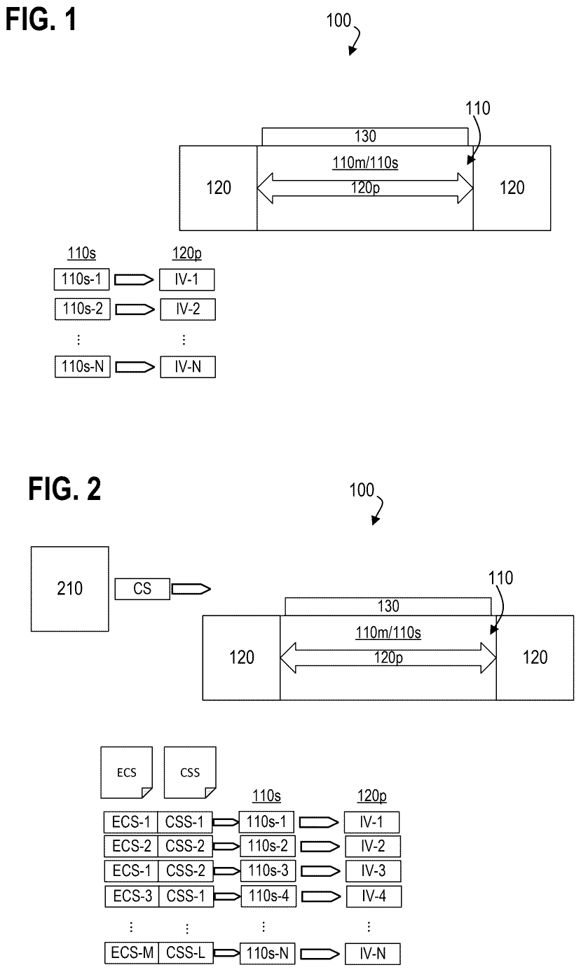

FIG. 1 shows a memristive transistor structure 100, according to various aspects. The memristive transistor structure 100 may include a channel portion 110. The channel portion 110 may include a memristive material 110m. According to various aspects, the memristive material 110m is a semiconductive memristive material such as an n-type or p-type semiconductive memristive material. For a transistor operation, the memristive material 110m may be brought into a predefined memristive operation state. In other words, the memristive material 110m may be preconfigured (e.g., written) to be in one of its plurality of possible memristive states 110s. Various electrode structures can be used to operate the memristive transistor structure 100. One or more electrodes may directly contact the channel portion 110 to cause an electric field within the channel portion 110 and/or to cause an electric current through the channel portion 110. One or more electrodes may be capacitively coupled with the channel portion 110 to cause an electric field within the channel portion 110 without causing a substantive current injection into the channel portion 110.

As an example, the memristive transistor structure 100 may include at least two source/drain electrodes 120 associated with the channel portion 110 and configured to provide an electric current path 120p between the at least two source/drain electrodes 120 through the channel portion 110. As an example, the memristive transistor structure 100 may include one or more gate electrodes 130 associated with the channel portion 110 and configured to allow for a change of a resistance of the channel portion 110 as a function of an gate electrode signal supplied to the one or more gate electrodes 130.

According to various aspects, in the case that the memristive operation state selected for the memristive material 110m is a first memristive state 110s-1 selected from a plurality of possible memristive states 110s, the electric current path 120p has a first current/voltage (I/V) characteristic IV-1. Moreover, in the case that the memristive operation state selected for the memristive material 110m is a second memristive state 110s-2 selected from a plurality of possible memristive states 110s, the electric current path 120p has a second current/voltage (I/V) characteristic IV-2. In total, the memristive material 110m may have a total number of N possible memristive states 110s-N associated therewith leading to the possibility of selecting from a number of N different current/voltage (I/V) characteristic IV-N for the operation of the memristive transistor structure 100. The respectively memristive state selected for operation is referred to herein as memristive operation state.

According to various aspects, one or more electric configuration (write) signals CS may be applied to one or more of the electrodes of the memristive transistor structure 100 to bring (e.g., to select, to write) the memristive state in which the memristive material 110m of the channel portion 110 is residing in during operation of the memristive transistor structure 100. The memristive transistor structure 100 may include a control circuit 210 to apply the one or more electric configuration (write) signals CS.

FIG. 2 shows the memristive transistor structure 100 and the control circuit 210 in a schematic view, according to various aspects. The combination of one or ore more electric configuration signals CS supplied to the memristive transistor structure 100 and the respectively one or more electrodes (e.g., the one or more gate electrodes 130, e.g., the one or more source/drain electrodes 120) used to create a respective electric field (e.g., with a predefined field strength and a predefined spatial field distribution) brings the memristive material 110m and therefore the memristive transistor structure 100 into a respective memristive operation state. The control circuit 210 may be configured to supply the one or ore more electric configuration signals CS with a predefined signal strength (e.g., with a predefined maximum voltage) and with a predefined duration (e.g., with a predefined pulse duration) and with a predefined signal shape (e.g., with a triangular or rectangular signal shape for example) to the respective one or more electrodes for defining the respective memristive operation state in which the memristive material 110m is residing in during operation of the memristive transistor structure 100. In some aspects, the control circuit 210 may be configured to select and/or apply a configuration signal scheme CSS and an electrode configuration scheme ECS in accordance with a desired memristive operation state to be caused in the memristive material 110m.

The configuration signal scheme CSS may include one or more configuration signal schemes CSS-1, CSS-2, CSS-L to define the possibility of selecting from a number of N different memristive states for the memristive material 110m of the channel portion 110 and therefore from a number of N different current/voltage (I/V) characteristic IV-N for the operation of the memristive transistor structure 100. The electrode configuration scheme ECS may include one or more electrode configuration schemes ECS-1, ECS-2, ECS-M to define the possibility of selecting from a number of N different memristive states for the memristive material 110m of the channel portion 110 and therefore from a number of N different current/voltage (I/V) characteristic IV-N for the operation of the memristive transistor structure 100. It is understood that a configuration signal scheme CSS may correspond to one operation electrode configuration scheme ECS to define the different memristive states of the memristive material 110m of the channel portion 110 due to the respectively cause electric field distribution in the channel portion 110. However, a same configuration signal scheme CSS can be combined with more than one different electrode configuration schemes ECS and/or different configuration signal schemes CSS can be combined with a same electrode configuration scheme ECS to define the different memristive states of the memristive material 110m of the channel portion 110 due to the respectively cause electric field distribution in the channel portion 110.

The one or more configuration signal schemes CSS-1, CSS-2, CSS-L may define one or more different signal types (e.g., distinct in at least one of signal strength, signal shape, signal duration, and the like). The one or more configuration signal schemes CSS-1, CSS-2, CSS-L may define the number of configuration signals CS supplied to the number of electrodes of the memristive transistor structure 100.

The electrode configuration scheme ECS may define the number of electrodes and/or the position of electrodes used for creating the electric field in the memristive material 110m of the memristive material 110m via the configuration signals CS. In some aspects, one or more gate electrodes 130 of the memristive transistor structure 100 may be used to bring the memristive material 110m into a predefined memristive operation state via the one or more corresponding configuration signals CS. In some aspects, one or more gate electrodes 130 and one or more source/drain electrodes 120 of the memristive transistor structure 100 may be used to bring the memristive material 110m into a predefined memristive operation state via the one or more corresponding configuration signals CS. In some aspects, one or more source/drain electrodes 120 of the memristive transistor structure 100 may be used to bring the memristive material 110m into a predefined memristive operation state via the one or more corresponding configuration signals CS.

According to various aspects, the control circuit may be configured to supply the one or more configuration signals CS to at least one of the at least two source/drain electrodes 120 and/or the one or more gate electrodes 130 of the memristive transistor structure 100 to modify (e.g., to set; e.g., to change) a memristive state 110s of the channel portion 110 during a configuration operation to set the memristive material 110m of the channel portion 110 into a predefined memristive operation state. In some aspects, the control circuit may be configured to provide the one or more configuration signals CS to cause a voltage drop over at least two of the gate electrodes 130. In some other aspects, the control circuit may be configured to provide the one or more configuration signals CS to cause a voltage drop over one of the at least two source/drains electrodes and one of the one or more gate electrodes 130.

According to some aspects, the control circuit may be configured to provide the one or more configuration signals CS to cause a voltage drop over the at least two source/drains electrodes. In this case, to cause a substantive electric field in the memristive material 110m of the channel portion 110, the memristive material 110m may be in a high resistive state. Such a high resistive state can be caused by applying an additional electric field via the one or more gate electrodes 130 prior to or at the same time as the application of the one or more configuration signals CS.

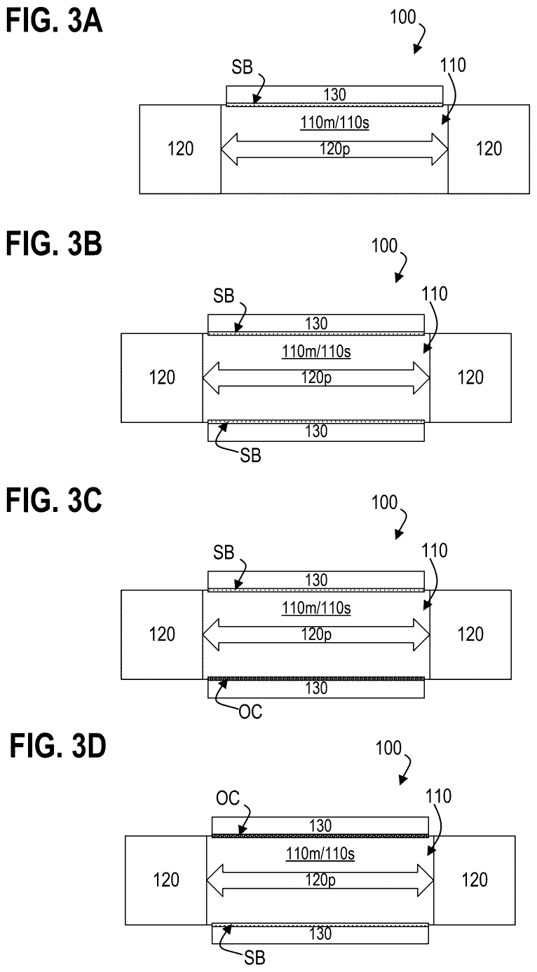

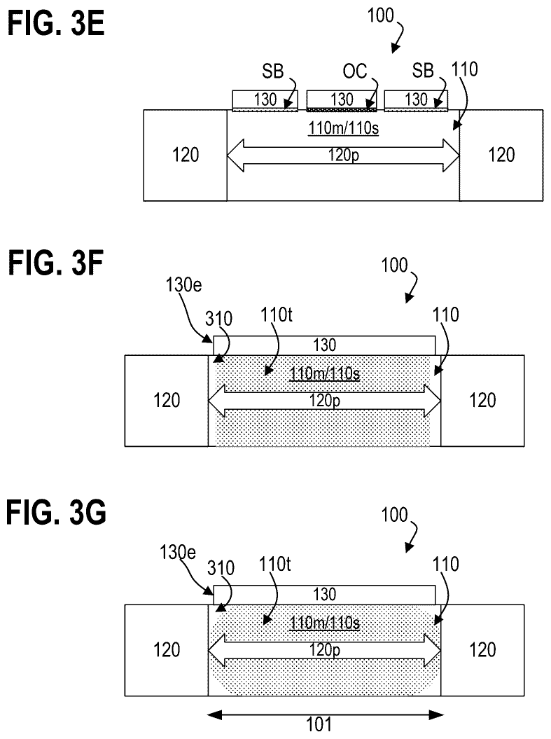

FIG. 3A, FIG. 3B, FIG. 3C, FIG. 3D, FIG. 3E, FIG. 3F, and FIG. 3G show various aspects of the memristive transistor structure 100 as described herein. The configuration of the one or more electrodes of the memristive transistor structure 100 and the channel portion 110 may be implemented to form, for example, one or more Schottky-Barriers SB in a respective interface region in which an electrode (e.g., one or more of the gate electrodes 130) contacts the channel portion 110. In some aspects, the one or more Schottky-Barriers SB may result from intrinsic material properties of the semiconductive memristive material 110m due to the direct contact with a metal of the respective electrode. However, in other aspects, the memristive material 110m may be configured to allow for a movement of charge carrier (e.g., ions or ion-vacancies) within the memristive material 110m (e.g., for a BiFeO memristive material or in a suitable perovskite oxide material, for example). In the case that the memristive material 110m allows for a reconfiguration of charge carrier (in some aspects the charge carrier may be ion dopants or ion-vacancy dopants, in some aspects the moveable charge carrier are not considered to be the free charge carrier of the material such as free electrons for example, in some aspects, the movement of charge carrier that is referred to with regard of the reconfiguration of the memristive material 110m is understood as a activatable drift process as soon as an electric field density exceeds a threshold value that overcomes the trapping of the charge carrier within the memristive material 110m) within the memristive material 110m, the electric field caused by the one or more gate electrodes 130 (e.g., during a configuration operation) can be used to move charge carrier towards the interface between a gate electrode 130 and the memristive material 110m and thereby change the local charge carrier density. As a result, the formation of the Schottky-Barrier SB can be prevented or cancelled and instead an ohmic contact OC remains or is formed at that interface between the gate electrode 130 and the memristive material 110m, as shown in FIG. 3C and FIG. 3D.

According to various aspects, a Schottky-Barrier may be associated with a corresponding barrier height and a corresponding shunt resistance. An ohmic contact may be associated with a Schottky-Barrier having a comparatively low shunt resistance and a comparatively low barrier height. In other words, formation and/or modification of the Schottky-Barriers in the channel portion 110 (as described herein) may include modifying the Schottky-Barrier in at least one of the shunt resistance and/or the barrier height. Reducing the shunt resistance may lead to the more ohmic behavior (ohmic contact OC) and increasing the shunt resistance may lead to the more Schottky-Barrier behavior (Schottky-Barrier SC) as described herein. Reducing the barrier height may lead to the more ohmic behavior (ohmic contact OC) and increasing the barrier height may lead to the more Schottky-Barrier behavior (Schottky-Barrier SC) as described herein. In other words, the ohmic contact OC described herein may be a modified Schottky-Barrier with a lower barrier height (e.g., at least a factor two lower) and a lower shunt resistance (e.g., at least a factor 10 lower) than the Schottky-Barrier SC.

As an example, ion-vacancies (e.g., oxygen vacancies in an oxide memristive material 110m) are moved in direction perpendicular to a surface of the gate electrode 130 (e.g., from one of the gate electrodes 130 to the other one of the gate electrodes 130), a Schottky-Barrier SB is formed at one of the gate electrodes 130 and an ohmic contact OC is formed at the other one of the gate electrodes 130, as shown in FIG. 3C and FIG. 3D. The reconfiguration of ion-vacancies within the memristive material 110m may modify the barrier height and/or the shunt resistance of the involved barriers between the semiconductive memristive material 110m and the metallic electrodes contacting the semiconductive memristive material 110m.

Therefore, a memristive state of the memristive material 110m may also include a charge carrier distribution (e.g., an spatial ion-distribution and/or a spatial ion-vacancy distribution) with respect to the one or more interfaces between the memristive material 110m and the one or more gate electrodes 130 of the memristive transistor structure 100.

FIG. 3E shows a schematic illustration of a memristive transistor structure 100 having a set of gate electrodes 130 (e.g., including at least two gate electrodes 130) arranged along the channel portion 110 between the source/drain electrodes 120. In some aspects, one or more of the set of gate electrodes 130 may be configured to cause a Schottky-Barrier SB between the respective gate electrode 130 and the memristive material 110m and one or more other of the set of gate electrodes 130 may be configured to cause on ohmic contact OC between the respective gate electrode 130 and the memristive material 110m. This asymmetric configuration can be achieved by applying voltages with opposite polarities to the respective sets of electrodes to either cause a drift of the charge carrier towards or wary from the interface between the channel portion 110 and the respective gate electrode 130.

In some aspects, the charge carrier for configuring the memristive transistor structure 100 into a specific state (defined by the respective state 110s in which the memristive material 110m is residing in) may be ion dopants or ion-vacancy dopants trapped in the memristive material 110m and being moveable (considered as a drift process). The movement (drift) of such trapped charge carrier is activatable by causing (e.g., via the one or more electrodes 120/130 and the one or more configuration signals CS) an electric field density above a threshold to overcome the trapping of the charge carrier within the memristive material 110m).

FIG. 3F and FIG. 3G show various spatial distributions of traps 110t in the memristive material 110m of the channel portion 110. As an example, the trap density may be low (compared for example to the center of the channel portion 110) or no traps may be present (e.g., introduced) in corner regions 310 between edges 130e of the gate electrodes 130 and the source/drain electrodes 120. In some aspects, the distribution of the traps in lateral direction (along the lateral extension 101 of the channel portion 110) at the interface with a gate electrode 130 may be less than the lateral dimension of the gate electrode 130. The trap distribution as described with reference to FIG. 3F und FIG. 3G may be suitable to reduce a source/drain leakage current and/or a gate/source or gate/drain leakage current. Traps may be defects in the memristive material 110m caused by adapted thin film growth methods and/or by ion bombardment during and/or after the growth of the memristive material 110m, for example. Traps may include intrinsic material defects or vacant crystal positions for example. Traps may include dopants such as metal dopants. The trap dopants may be neutral with respect to the electronic doping (e.g., titanium atoms in BiFeO as memristive material 110m may be used as trapping dopants to control oxygen vacancy trapping, wherein the oxygen vacancy distribution in the BiFeO define the memristive state 110s of the memristive material 110m).

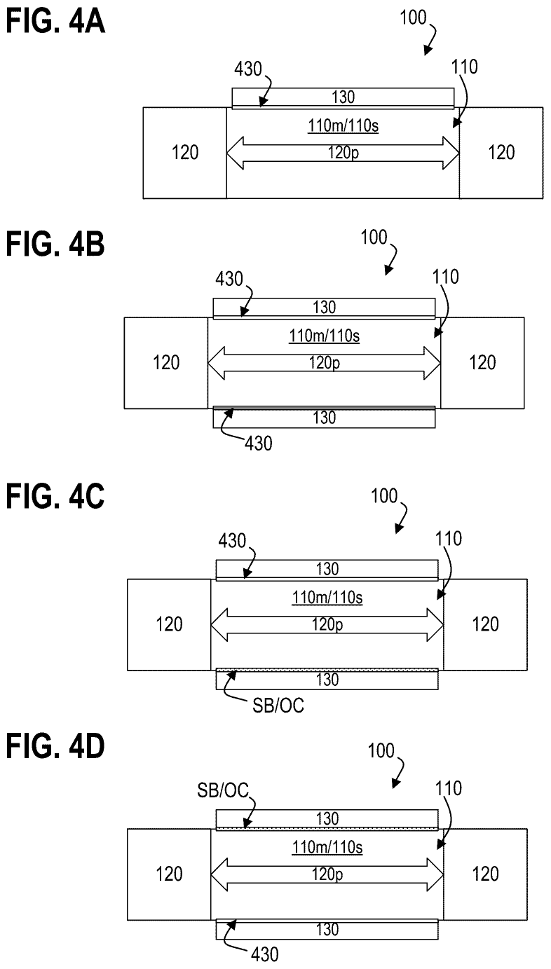

FIG. 4A, FIG. 4B, FIG. 4C, and FIG. 4D show various aspects of the memristive transistor structure 100 as described herein. The configuration of the one or more electrodes of the memristive transistor structure 100 and the channel portion 110 may be implemented to form, for example, a capacitive coupling of an electrode (e.g., one or more of the gate electrodes 130) with the channel portion 110. In some aspects, a gate isolation 430 may be formed between the semiconductive memristive material 110m and the respective electrode, as shown in FIG. 4A and FIG. 4B. In some other aspects, one of the gate electrodes 130 may be in direct contact with the semiconductive memristive material 110m to form a configurable Schottky barrier SO/OC (as described above) and another one of the gate electrode 130 may be capacitively coupled to the memristive material 110m of the channel portion 110 by a gate isolation 430, as shown in FIG. 4C and FIG. 4D.

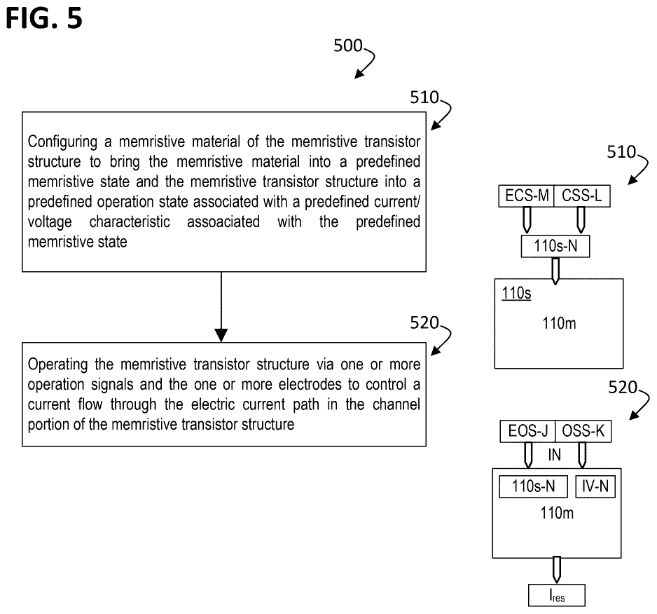

FIG. 5 shows a method 500 for operating a memristive transistor structure 100, according to various aspects. The method 500 may include, in 510, configuring a memristive material 110m of the memristive transistor structure 100 to bring the memristive material 110m into a predefined memristive state 110s and the memristive transistor structure 100 into a predefined operation state associated with a predefined current/voltage characteristic IV associated with the predefined memristive state 110s (see FIG. 2). A (predefined) memristive state 110s that defines an operation state of the memristive transistor structure 100 may be referred to herein as (predefined) memristive operation state. The configuring of the memristive material 110m may include applying one or more control signals CS to one or more electrodes 120/130 of the memristive transistor structure 100 to bring (write) the memristive material 110m into the predefined memristive state 110s.

Configuring the memristive material 110m (e.g., in 510 of method 500) may include to cause a predefined spatial distribution of bound (e.g., dopants, intrinsic) charge carrier. This can be achieved by generating (via the one or more electrodes and the one or more control signals) a predefined electric field for a predefined time to allow for a drift of the bound charge carrier into the predefined spatial distribution. It is understood that the predefined spatial distribution is considered as a spatial distribution in terms of charge carrier concentration (e.g., a three dimensional profile related to the locations of the charge carrier).

The method 500 may include, in 520, operating the memristive transistor structure 100 via one or more operation signals OS (e.g., defined for operation by an operation signal scheme OSS) and the one or more electrodes 120/130 (e.g., defined for operation via an electrode operation scheme EOS) to control a current flow through the electric current path 120p in the channel portion 110 of the memristive transistor structure 100. The current flow through the electric current path 120p during operation of the memristive transistor structure 100 may be defined by the predefined current/voltage characteristic IV set during the configuration in 510. According to various aspects, the operation state in which the memristive transistor structure 100 is operated after configuration is defined by the respectively selected combination of the electrode operation scheme EOS and the operation signal scheme OSS. As an example, the memristive transistor structure 100 may be operated by supplying at least one source/drain voltage to at least one of the source/drain electrodes 120 and at least one gate voltage to at least one of the one or more gate electrodes 130 to cause a predefined current (Iᵣₑₛ) in the channel portion 110 in accordance with the respective present current/voltage (I/V) characteristic IV-N of the memristive material 110m.

During operation (e.g., in 520 of method 500) of the memristive transistor structure 100 it may be desired to keep the predefined memristive state 110s-N unchanged. In other words, the memristive material 110m may not change the spatial distribution of bound charge carrier (e.g., of the dopant ions or ion-vacancies) in channel portion 110 during the operation of the memristive transistor structure 100 (e.g., in 520 of method 500). Therefore, the one or more operation signals OS (e.g., defined for operation by the operation signal scheme OSS) and the one or more electrodes 120/130 used for applying the one or more operation signals OS (e.g., defined for operation via an electrode operation scheme EOS) may be selected to not change the memristive state 110s-N set during the configuration process in 510 of method 500. This may include that the maximum voltages of the one or more operation signals OS may be less than the maximum voltages of the one or more configuration signals CS.

In some aspects, the electrode operation scheme EOS during operation (e.g., in 520 of method 500) may be the same as the electrode configuration scheme ECS during configuration (e.g., in 510 of method 500). However, in other aspects, it may be beneficial to use another set of electrodes for the operation compared to the configuration and in this case, the electrode operation scheme EOS during operation (e.g., in 520 of method 500) may be different from the electrode configuration scheme ECS during configuration (e.g., in 510 of method 500). There may be a number of J possibilities for using the electrodes to operate the memristive transistor structure 100 corresponding to a number of J electrode operation scheme EOS-J. There may be a number of K possibilities for using the operation signals OS to operate the memristive transistor structure 100 corresponding to a number of K operation signal scheme OSS-K. The response (e.g., the response current Iᵣₑₛ) of the memristive transistor structure 100 is caused by the respective the input IN (e.g., one or more input voltages), for example, as a function of the selected electrode operation scheme EOS-J and of the selected operation signal scheme OSS-K.

The operation of the memristive transistor structure 100 may include typical transistor functions such as a modification of the depletion region in the channel portion 110. The modification of the depletion region includes, for example, a relocation of free charge carrier (e.g., majority charge carrier, e.g., electrons in n-type; e.g., holes in p-type; e.g., minority charge carrier, e.g., holes in n-type, e.g., electrons in p-type). The modification of the modification of the depletion region (e.g., by supplying at least one gate voltage to at least one of the one or more gate electrodes 130) defines the current flow (Iᵣₑₛ) through the channel portion 110 upon supplying a source voltage to one of the source/drain electrodes 120.

According to various aspects, a predefined electric field profile can be created in the channel portion 110 to define a spatial dopant distribution in the channel portion 110 (i.e., to define a memristive state of the memristive material and an operation state of the memristive transistor structure) depending on the choice and the relative position of the electrodes (used to create the electric field profile) with respect to the memristive material 110m of the channel portion 110.

According to various aspects, one of the contacts (e.g., the contacts between a gate electrode and the channel portion 110) can be a rectifying contact (e.g., a Schottky contact). According to some aspects, ion-vacancy dopants may not be trapped between gate and the source/drain of the memristive transistor structure 100. After configuration, e.g., after 510 of method 500 is carried out, ion-vacancy dopants may be only trapped in regions of the channel portion 110 where traps are present in the memristive material 110m.

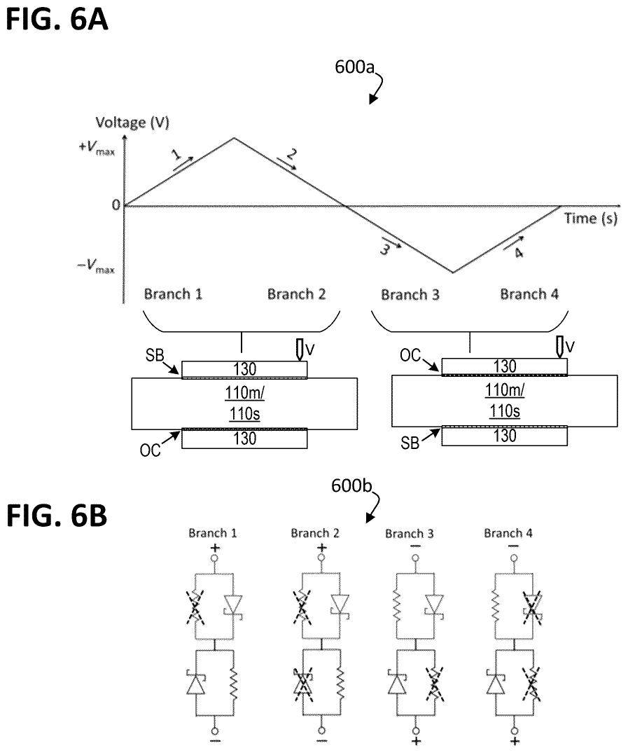

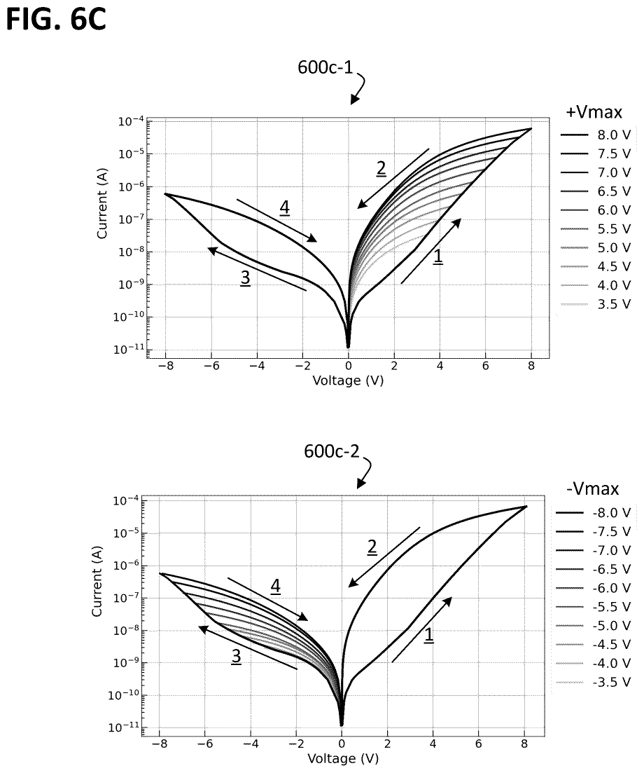

FIG. 6A, FIG. 6B, and FIG. 6C show a set of diagrams 600a, 600b, 600c-1, 600c-2 illustrating the behavior of a memristive material 110m having a switchable barrier function, e.g., such as memristive BiFeO based material. The memristive material 110m can be disposed in an electric field caused by two gate electrodes 130 as shown for example in FIG. 3B, FIG. 3C, and FIG. 3D, wherein the memristive material 110m is disposed between the two gate electrodes 130. The electric field is caused by a gate voltage supplied to one of the two gate electrodes 130, wherein the other one of the two gate electrodes 130 has ground potential. However, there are various well-known other possibilities to cause the same or a similar electric field.

As illustrated in FIG. 6A in diagram 600a, the response of the memristive material 110m caused by the electric field (represented by the voltage V) may allow for four distinct basic configurations reflected in branches 1 to 4 of the hysteresis loop as shown in FIG. 6C. Upon applying a positive voltage up to +Vmax on branch 1, the memristive material 110m is written (configured) into a predefined memristive state related to the respective +Vmax (see FIG. 6C showing in diagram 600c-1 various curves of the hysteresis loop for different +Vmax). This first ramp to +Vmax is referred to as a first (e.g., positive) write branch. The writing (configuring) of the memristive material 110m is associated with a change (e.g., a drift, a relocation, as examples) in the bound charge carrier as described herein. After the writing of the memristive material 110m along branch 1 up to +Vmax, the lower voltages of branch 2 are not associated with a change in the bound charge carrier and therefore referred to as a first read branch. As soon as the memristive material 110m is configured along branch 1 up to +Vmax, the memristive material 110m can be operated in this voltage range between 0 V and +Vmax without changing the memristive state 110s thereof along corresponding branch 2. The barrier configurations of branches 1 and 2 are shown in FIG. 6B and the I/V curves of the hysteresis loop associated with the writing and reading in branches 1 and 2 are shown in diagram 600c-1 of FIG. 6C.

Upon applying a negative voltage along branch 3 to −Vmax, the memristive material 110m is written (reconfigured) into branch 3, which is referred to as a second (e.g., negative) write branch. This writing (configuring) of the memristive material 110m along branch 3 is associated again with a change (e.g., a drift, a relocation, as examples) in the bound charge carrier as described herein (due to the opposite electric field direction). After the writing of the memristive material 110m along branch 3 down to −Vmax, the higher voltages of branch 4 (between −Vmax and 0 V) are not associated with a change in the locations of the bound charge carrier and therefore referred to as a second read branch similar to the first read branch. As soon as the memristive material 110m is configured along branch 3 with −Vmax, the memristive material 110m can be operated in this voltage range between 0 V and −Vmax without changing the memristive state 110s thereof. The barrier configurations of branches 3 and 4 are shown in FIG. 6B and the I/V curves of the hysteresis loop associated with the writing and reading in branches 3 and 4 are shown in diagram 600c-2 of FIG. 6C.

FIG. 6C shows—in logarithmic scale—an exemplary I/V hysteresis loop corresponding to a voltage sweep as shown in FIG. 6A from 0V to +Vmax to 0V to −Vmax to 0V for different +Vmax and different −Vmax. It is illustrated that each branch 1 to 4 (labeled with 1, 2, 3, 4) corresponds to a part of the I/V hysteresis loop showing two write branches 1 and 3 with a change in the memristance of the memristive material 110m and two read branches 2 and 4 with substantially no change in the memristance of the memristive material 110m as long as the voltages of the reading are below the corresponding ±Vmax. The I/V behavior of a read branch corresponding to its Vmax of the write branch is constant as along as no further writing to greater Vmax of the same polarity or to a Vmax of the opposite polarity is caused by the applied voltage(s).

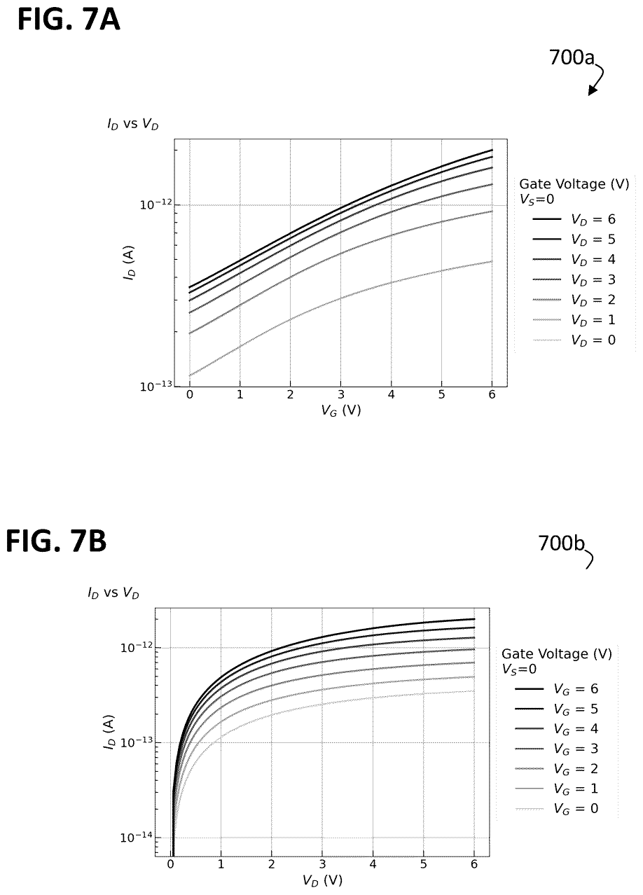

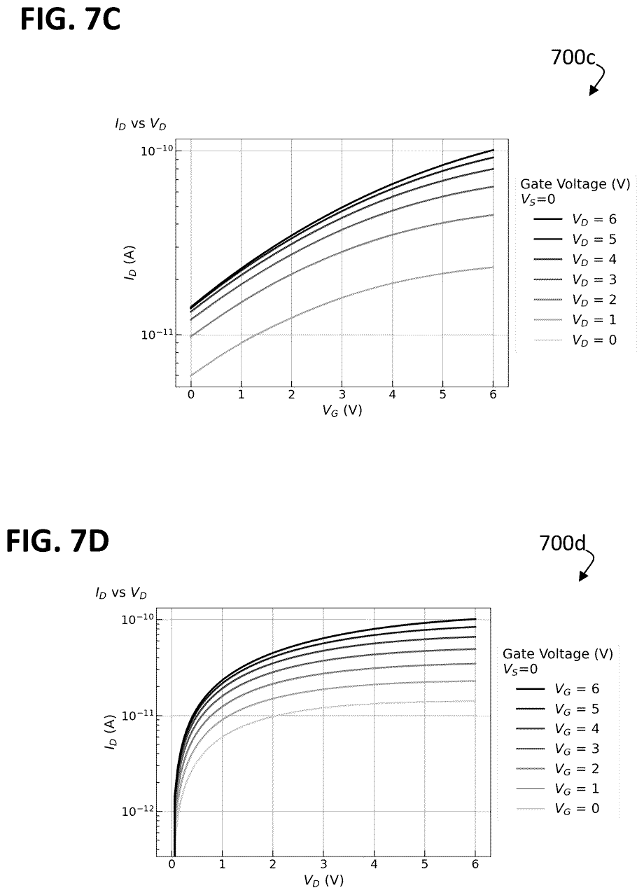

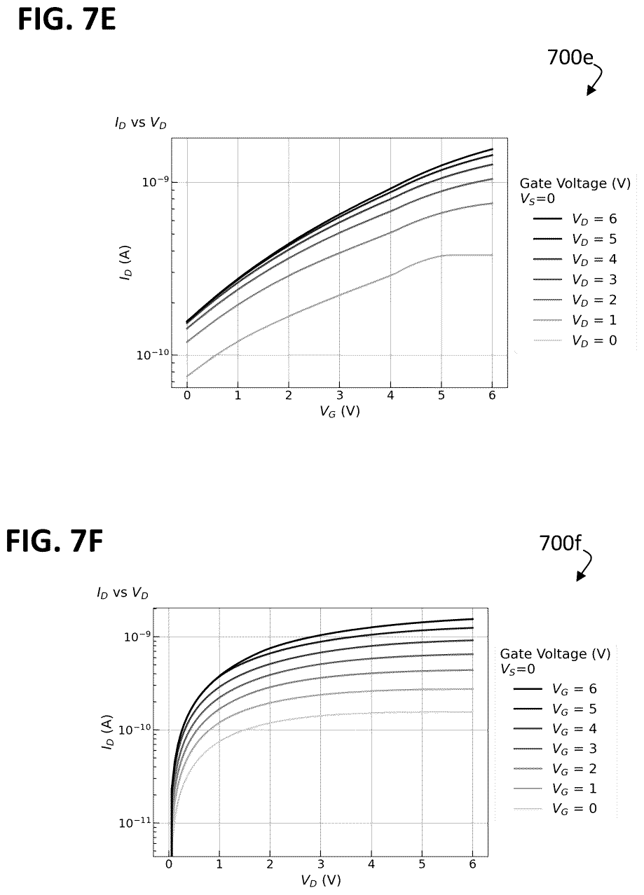

FIG. 7A and FIG. 7B illustrate—for a first memristive state of the memristive material, a source/drain current flow (Ids) behavior of the electric current path as a function of different gate voltages (V_{G}) and drain voltages (V_{D}) for a memristive transistor structure as described herein. FIG. 7C and FIG. 7D illustrate—for a second memristive state of the memristive material, a source/drain current flow (Ids) behavior of the electric current path as a function of different gate voltages (V_{G}) and drain voltages (V_{D}) for a memristive transistor structure as described herein. FIG. 7E and FIG. 7F illustrate—for a third memristive state of the memristive material, a source/drain current flow (Ids) behavior of the electric current path as a function of different gate voltages (V_{G}) and drain voltages (V_{D}) for a memristive transistor structure as described herein. The memristive transistor structure may be configured as shown, for example, in FIG. 1, FIG. 2, and FIGS. 3A to 3G. The gate voltages (V_{G}) may be applied between the gate electrode and the source electrode or between two gate electrodes and the drain voltages (V_{D}) are applied between source drain electrode of the memristive transistor structure. The drain current (I_{D}) may be an electric current determined in the current path (e.g., current path 120p) between the source electrode and the drain electrode of the memristive transistor structure.

Diagrams 700a, 700c, 700e show the drain current I_{D} as a function of the gate voltage V_{G} for different constant drain voltages V_{D} and diagrams 700b, 700d, 700f show the drain current I_{D} as a function of the drain voltage V_{D} for different constant gate voltages V_{G}. FIGS. 7A and 7B show the memristive transistor structure 100 in a configuration with a MESFET behavior in which the memristive material 110m was written into its predefined memristive state 110s with a write voltage of +Vmax=3.5 V. FIGS. 7C and 7D show the memristive transistor structure 100 in a configuration with a MESFET behavior in which the memristive material 110m was written into its predefined memristive state 110s with a write voltage of +Vmax=6 V. FIGS. 7E and 7F show the memristive transistor structure 100 in a configuration with a MESFET behavior in which the memristive material 110m was written into its predefined memristive state 110s with a write voltage of +Vmax=8 V.

With reference to memristive transistor structure 100 described above, the drain current I_{D} is determined between the at least two source/drain electrodes 120 of the memristive transistor structure 100, wherein the one of the at least two source/drain electrodes 120 having the smaller voltage applied thereto is referred to as drain electrode 120 and wherein the other one of the at least two source/drain electrodes 120 having the greater voltage applied thereto is referred to as source electrode 120. The gate voltage VG may be applied to the gate electrode 130 of the memristive transistor structure 100 wherein the source electrode 120 may be kept on a reference voltage (e.g., at ground voltage). In other aspects, the gate voltage may be applied and determined between two gate electrodes 130 of the memristive transistor structure 100 (see, for example FIGS. 3B, 3C, and 3D and FIGS. 4B, 4C, and 4D for a configuration in which the memristive transistor structure 100 has two gate electrodes and the memristive material 110m of the channel portion 110 disposed therebetween).

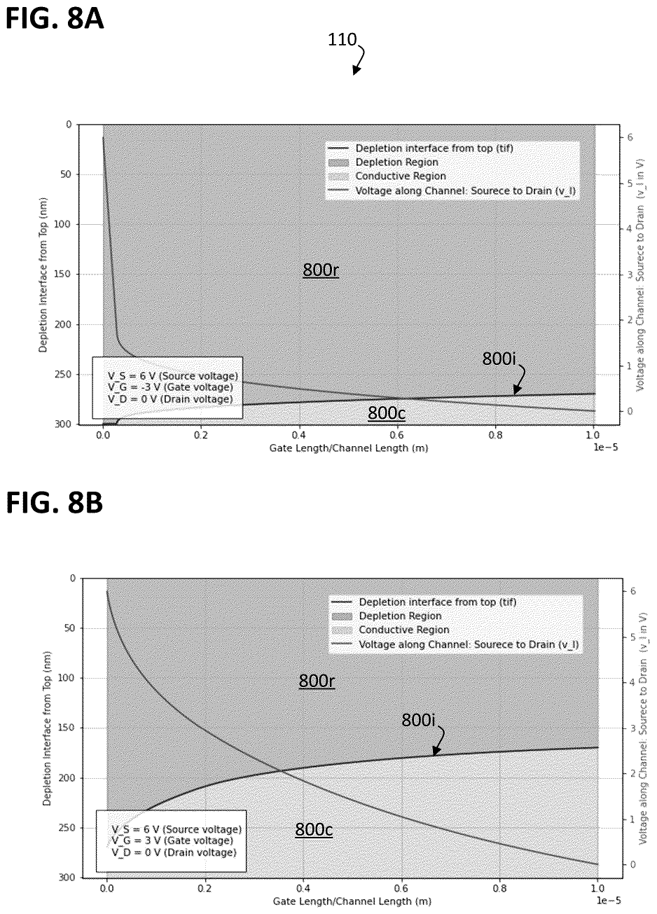

FIG. 8A and FIG. 8B illustrate a formation of the depletion region 800r along the channel (horizontal axis) with the depletion interface 800i (vertical axis) depth measured from the top interface between the memristive material 110m and the gate electrode 130, for example. According to various aspects, the location of the depletion interface 800i is a function of the applied gate voltage and may be influenced as well by the applied source/drain voltage.

As shown in FIG. 8A, the conductive region 800c does not connect the source/drain electrodes in the case that a −3 V gate voltage is applied with a +6 V source/drain voltage. Thus, the memristive transistor structure 100 is in a non-conductive state and shows no significant source/drain current. However, as shown in FIG. 8B, the conductive region 800c connects the source/drain electrodes in the case that a +3 V gate voltage is applied with a +6 V source/drain voltage. Thus, the memristive transistor structure 100 is in a conductive state and shows a significant source/drain current. FIG. 8A and FIG. 8B show the transistor function of the memristive transistor structure 100 for a predefined operation state (e.g., with a constant memristance). The transistor function is defined by the depletion region and its location in the channel portion 110 relative to the source/drain electrodes 120.

Various logic circuits or other electronic circuits (e.g., an analog or digital inverter circuit) can be designed based on the memristive transistor structure 100. According to various aspects, the memristive transistor structure 100 can be operated as single memristive transistor structure 100, in a series connection with one or more additional memristive transistor structures 100 and/or in a parallel connection with one or more additional memristive transistor structures 100. Some examples are provided in more detail in the following.

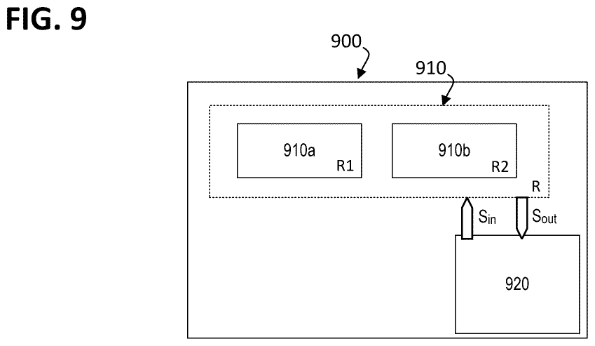

FIG. 9 shows an electronic circuit 900 in a schematic view, according to various aspects. The electronic circuit 900 may include one or more memristive circuits 910. Each of the one or more memristive circuits 910 may include a plurality of memristive transistor structures, e.g., one or more memristive transistor structures 100 as described herein.

In the example illustrated in FIG. 9, the electronic circuit 900 includes a memristive circuit 910 with a first memristive transistor structure 910a and with a second memristive transistor structure 910b. The first and second memristive transistor structure 100 are electrically coupled to one another, e.g., in a series connection or in a parallel connection.

According to various aspects, the electronic circuit 900 may include a control circuit 920. The control circuit 920 may be configured to supply one or more input signals Sᵢₙ to the memristive circuit 910. The control circuit 920 and/or memristive circuit 910 may be configured to output one or more output signals Sₒᵤₜ from the memristive circuit 910. The one or more output signals Sₒᵤₜ may be output to an external circuit or external device or may be processed further internally in the electronic circuit 900. According to various aspects, the one or more output signals Sₒᵤₜ may be a function of a response R of the memristive circuit 910 caused by the one or more input signals Sᵢₙ.

According to various aspects, the response R of the memristive circuit 910 may be an electric current response caused by supplying one or more voltage input signals to the two or more memristive transistor structures 910a, 910b thereof. In other aspects, the response R of the memristive circuit 910 may be a voltage response caused by supplying one or more electric current input signals to the two or more memristive transistor structures 910a, 910b thereof. An electric current signal may be electric current controlled and a voltage signal may be voltage controlled by suitable electric current controllers or voltage controllers included, for example, in the control circuit 920.

According to various aspects, the one or more operation signals OS supplied to a memristive transistor structure 100—as described herein—(see for example FIG. 5) may be considered as input signals Sᵢₙ and may cause a response R1, R2 in each of the memristive transistor structures 910a, 910b. The response R of the memristive circuit 910 is based on both responses R1, R2 of the at least two memristive transistor structures 910a, 910b of the memristive circuit 910.

The electronic circuit 900 may be configured as an inverter using two memristive transistor structures 100 of a very same type, e.g., two n-type memristive transistor structures 100. In this case, for example, one (e.g., a first) memristive transistor structure 100 is used as a switching element (in a common-source configuration) with a resistor or a second memristive transistor structure 100 providing the pull-up or pull-down function. Using the second memristive transistor structure 100 in a series connection with the first memristive transistor structure 100 may allow for a design in which the second memristive transistor structure 100 is an active load by biasing the second memristive transistor structure 100 appropriately.

The active load can be arranged so that it provides a more predictable voltage level than a simple resistor, although matching and biasing become critical. However, writing the second memristive transistor structure 100 into a predefined memristive state may allow for matching and biasing the active load.

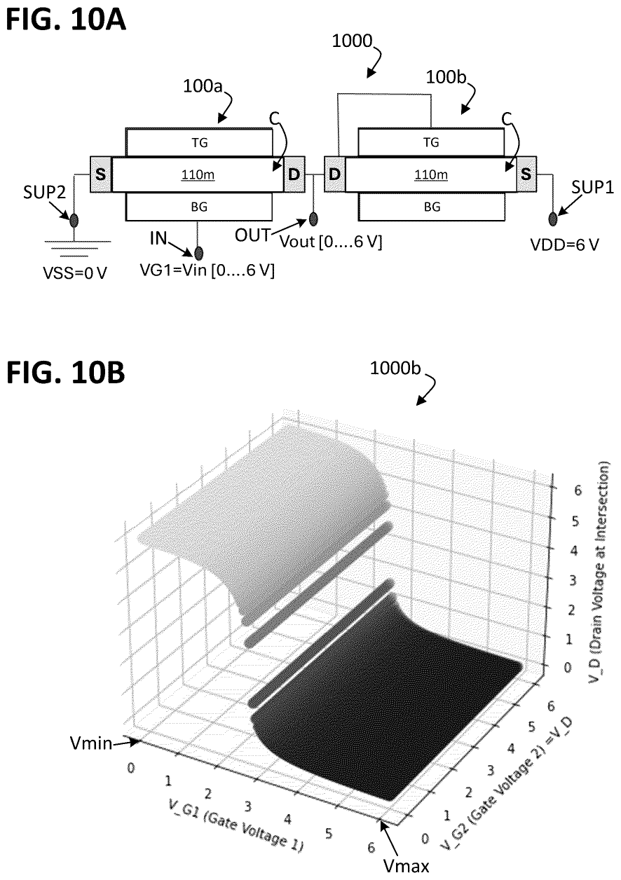

FIG. 10A shows an inverter circuit 1000 including at least two memristive transistor structures 100a, 100b coupled to one another. The inverter circuit 1000 includes an input node IN to receive an input signal VG1 to be inverted. In an example, the input signal VG1 may be a voltage signal in the voltage range of 0 V to 6 V. However, any other suitable input signal may be used in a similar way. The inverter circuit 1000 includes an output node OUT to output an output signal Vout as an inverted signal from the input signal. In an example, the output signal Vout may be a voltage signal in the voltage range of 0 V to 6 V. However, any other suitable output signal may be used in a similar way. In some aspects, the inverter circuit 1000 may be configured to operate with the input signal and output signal in the very same voltage range. According to various aspects, the inverter circuit 1000 include two supply nodes SUP1, SUP2 to receive for example a VDD supply signal and a VSS supply signal. The supply signals VDD, VSS may be defined the operation voltage range of the inverter circuit 1000.

According to various aspects, the least two memristive transistor structures 100a, 100b of the inverter circuit 1000 may be coupled to one another in a series connection and each of the least two memristive transistor structures 100a, 100b having a source electrode S, a drain electrode D, and two gate electrodes TG, BG (e.g., a top gate and a bottom gate) to operate the respective memristive transistor structures 100a, 100b as described herein. The respective channel C of the memristive transistor structure 100a, 100b includes a memristive material 110m as described herein. There may be configurations in which only one of the least two memristive transistor structures 100a, 100b include a memristive material 110m and the other one includes a non-memristive semiconductor material.

According to some aspects, one of the memristive transistor structures (e.g., memristive transistor structure 100b) of the inverter circuit 1000 may have one of its gate electrodes (e.g., the top gate TG) conductively connected to its drain electrode D to realized the inverter function using only one input signal. In other aspects, the gate electrode may not be connected to the drain electrode but supplied with an additional input and/or control signal.

FIG. 10B shows an operation voltage diagram 1000b of the inverter circuit 1000 as shown in FIG. 10A, wherein the inverter circuit 1000 may be configured to receive the input signal V_G1 and output the corresponding output signal V_D based in the respectively caused gate voltage of the memristive transistor structure 100b having its drain electrode connected to its gate electrode. The diagram shows the inverter function that can be realized in a digital manner using only Vmin, Vmax for the input (e.g., 0 V and 6 V in this example) or in an analog manner using additionally one or more voltages in between of Vmin and Vmax. The inverter circuit 1000 may be configured and operated to realize a logic NOT function between one input signal and the output signal.

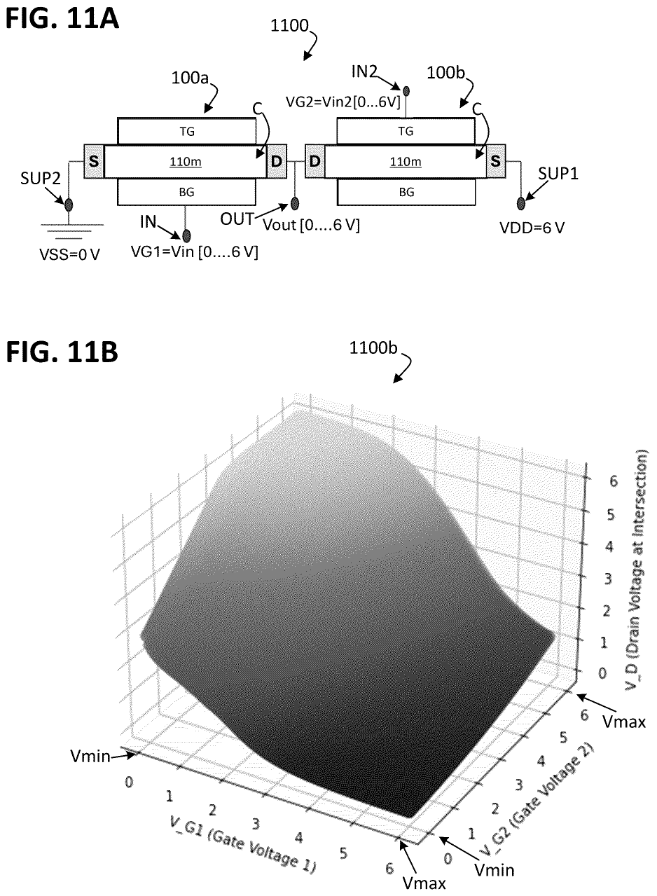

FIG. 11A shows a logic circuit 1100 including at least two memristive transistor structures 100a, 100b coupled to one another. The logic circuit 1000 may be configured and operated to realize a logic AND function between two input signals and the output signal. The logic circuit 1100 includes an input node IN to receive an input signal VG1 and an additional (second) input node IN2 to receive an additional (second) input signal VG2. In an example, the input signals VG1, VG2 may be voltage signals in the voltage range of 0 V to 6 V. However, any other suitable set of input signals may be used in a similar way. The logic circuit 1100 includes an output node OUT to output an output signal Vout as a function of the two input signals. In an example, the output signal Vout may be a voltage signal in the voltage range of 0 V to 6 V. However, any other suitable output signal may be used in a similar way. In some aspects, the logic circuit 1100 may be configured to operate with the two input signals and the output signal in the very same voltage range. According to various aspects, the logic circuit 1100 includes two supply nodes SUP1, SUP2 to receive for example a VDD supply signal and a VSS supply signal. The supply signals VDD, VSS may be defined the operation voltage range of the logic circuit 1100.

According to various aspects, the least two memristive transistor structures 100a, 100b of the logic circuit 1100 may be coupled to one another in a series connection and each of the least two memristive transistor structures 100a, 100b having a source electrode S, a drain electrode D, and two gate electrodes TG, BG (e.g., a top gate and a bottom gate) to operate the respective memristive transistor structures 100a, 100b as described herein. The respective channel C of the memristive transistor structure 100a, 100b includes a memristive material 110m as described herein. There may be configurations in which only one of the least two memristive transistor structures 100a, 100b include a memristive material 110m and the other one includes a non-memristive semiconductor material.

According to some aspects, one of the memristive transistor structures (e.g., memristive transistor structure 100a) of the logic circuit 1100 may receive a first input signal Vin as gate voltage VG1 at a gate electrode (e.g., the bottom gate BG) thereof and the other one of the memristive transistor structures (e.g., memristive transistor structure 100b) of the logic circuit 1100 may receive a second input signal Vin2 as gate voltage VG2 at a gate electrode (e.g., the top gate TG) thereof to realized the logic AND function using two input signals.

FIG. 11B shows an operation voltage diagram 1100b of the logic circuit 1100 as shown in FIG. 11A. The first input signal V_G1 and the second input signal V_G2 cause the corresponding output signal V_D. The diagram shows the logic function that can be realized in a digital manner using only Vmin, Vmax for the input (e.g., 0 V and 6 V in this example) or in an analog manner using additionally one or more voltages in between of Vmin and Vmax.

In the following, various examples are provided that may include one or more aspects described above with reference to the memristive structure and/or the memristive crossbar array. It may be intended that aspects described in relation to the memristive structure and/or the memristive crossbar array may apply also to one or more methods (e.g., a method for manufacturing a memristive structure and/or memristive crossbar array), and vice versa.

Example 1 is a memristive transistor structure including: a channel portion including a memristive material, wherein the memristive material is a semiconductive memristive material in a predefined memristive operation state; at least two source/drain electrodes associated with the channel portion and configured to provide an electric current path between the at least two source/drain electrodes through the channel portion; one or more gate electrodes associated with the channel portion and configured to change an electronic behavior of the channel portion.

In Example 2, the memristive transistor structure of Example 1 may optionally further include that the change of the electronic behavior of the channel portion during an operation of the memristive transistor structure is associated with a change in a resistance of the channel portion.

In Example 3, the memristive transistor structure of Example 1 or 2 may optionally further include: a control circuit configured to supply one or more configuration signals to at least one of at least two source/drain electrodes and/or the one or more gate electrodes to modify a memristive state of the channel portion during a configuration operation to set the predefined memristive operation state.

In Example 4, the memristive transistor structure of Example 3 may optionally further include that the control circuit is configured to provide the one or more configuration signals to cause a voltage drop over at least two of the gate electrodes.

In Example 5, the memristive transistor structure of Example 3 may optionally further include that the control circuit is configured to provide the one or more configuration signals to cause a voltage drop over one of the at least two source/drains electrodes and one of the one or more gate electrodes.

In Example 6, the memristive transistor structure of Example 3 may optionally further include that or that the control circuit is configured to provide the one or more configuration signals to cause a voltage drop over the at least two source/drains electrodes while the memristive material of the channel portion is in a high resistive state.

In Example 7, the memristive transistor structure of any one of Examples 1 to 6 may optionally further include that the memristive material is n-type doped.

In Example 8, the memristive transistor structure of any one of Examples 1 to 6 may optionally further include that the memristive material is p-type doped.

In Example 9, the memristive transistor structure of any one of Examples 1 to 6 may optionally further include that at least a first portion of the memristive material is p-type doped and that at least a second portion of the memristive material is n-type doped.

In Example 10, the memristive transistor structure of any one of Examples 1 to 9 may optionally further include that the channel portion and at least one of the one or more gate electrodes are configured as metal-semiconductor field-effect transistor (MeSFET) structure;

In Example 11, the memristive transistor structure of any one of Examples 1 to 10 may optionally further include that the channel portion and at least one of the one or more gate electrodes are configured as metal-insulator-semiconductor field-effect transistor (MISFET) structure.

In Example 12, the memristive transistor structure of any one of Examples 1 to 11 may optionally further include that the channel portion and at least one of the one or more gate electrodes form at least one Schottky-contact.

In Example 13, the memristive transistor structure of Example 12 may optionally further include that the memristive material is configured to selectively form the at least one Schottky-contact as a function of a write signal to change the memristive state of the memristive material.

In Example 14, the memristive transistor structure of Example 13 may optionally further include that the write signal is an electric voltage signal applied to at least one of the one or more gate electrodes.

In Example 15, the memristive transistor structure of any one of Examples 1 to 14 may optionally further include that the memristive material is configured to allow for a change in a spatial dopant distribution in the channel portion as a function of one or more electric signals applied to at least one of the one or more gate electrodes and/or to at least one of the at least two source/drain electrodes.

In Example 16, the memristive transistor structure of any one of Examples 1 to 15 may optionally further include that the one or more gate electrodes includes a first gate electrode and a second gate electrode, and that at least a part of the channel portion is disposed between the first gate electrode and the second gate electrode.

In Example 17, the memristive transistor structure of Example 16 may optionally further include that the memristive material is configured to allow for a change in a spatial dopant distribution in the channel portion to selectively form: (i) a Schottky-Barrier between the channel portion and the first gate electrode and an ohmic contact behavior between the channel portion and the second gate electrode (associated with a first memristive state); or (ii) a Schottky-Barrier between the channel portion and the second gate electrode and an ohmic contact behavior between the channel portion and the first gate electrode (associated with a second memristive state different from the first memristive state).

In Example 18, the memristive transistor structure of Example 16 may optionally further include that the memristive material is configured to allow for a change in a spatial dopant distribution in the channel portion to selectively form: (i) a first Schottky-Barrier between the channel portion and the first gate electrode and a second Schottky-Barrier between the channel portion and the second gate electrode, wherein at least one of a barrier height and/or a shunt resistance of the second Schottky-Barrier is lower compared to the first Schottky-Barrier (associated with a first memristive state); or (ii) a first Schottky-Barrier between the channel portion and the first gate electrode and a second Schottky-Barrier between the channel portion and the second gate electrode, wherein at least one of a barrier height and/or a shunt resistance of the first Schottky-Barrier is lower compared to the second Schottky-Barrier (associated with a second memristive state different from the first memristive state).

In Example 19, the memristive transistor structure of Example 17 or 18 may optionally further include that a plurality of memristive states (e.g., more than 10, more than 100, more than 1000, only as examples) can be configured (e.g., continuously) in the memristive material.

In Example 20, the memristive transistor structure of any one of Examples 1 to 19 may optionally further include that the at least two source/drain electrodes are configured to form each an ohmic contact with the channel portion.

In Example 21, the memristive transistor structure of any one of Examples 1 to 20 may optionally further include that the memristive material is reconfigurable between a first memristive state and a second memristive state, wherein a dopant distribution associated with the first memristive state is different from a dopant distribution associated with the second memristive state.

In Example 22, the memristive transistor structure of any one of Examples 18 to 21 may optionally further include that the memristive material is configured such that a change from the first memristive state to the second memristive state is associated with a drift of ions or ion-vacancies in the memristive material of the channel portion.

In Example 23, the memristive transistor structure of any one of Examples 1 to 22 may optionally further include that at least one of the one or more gate electrodes has a planar side facing the channel portion and wherein a dopant distribution in the channel portion is inhomogeneous along a direction perpendicular to the planar side.

In Example 24, the memristive transistor structure of any one of Examples 21 to 23 may optionally further include that the dopant distribution is an ion-distribution or an ion-vacancy distribution in the memristive material of the channel portion.

In Example 25, the memristive transistor structure of any one of Examples 1 to 24 may optionally further include that the memristive material includes traps for trapping ions or ion-vacancies to allow for a non-volatile presence of a respective memristive state defined by the spatial concentration distribution of the ions or ion-vacancies in the memristive material of the channel portion.

In Example 26, the memristive transistor structure of any one of Examples 1 to 25 may optionally further include that the memristive material is configured such that the change from the first memristive state to the second memristive state is associated with a drift of ions or ion-vacancies in the memristive material.

In Example 27, the memristive transistor structure of any one of Examples 1 to 26 may optionally further include that the memristive material is configured such that the change from the first memristive state to the second memristive state is associated with a formation of a gradient in a dopant distribution and/or with a change of a gradient in a dopant distribution.

In Example 28, the memristive transistor structure of any one of Examples 1 to 27 may optionally further include that the memristive material is a semiconductive oxide material.

In Example 29, the memristive transistor structure of Example 28 may optionally further include that the semiconductive oxide material includes oxygen vacancies and a gradient in a spatial concentration distribution of the oxygen vacancies in the semiconductive oxide material.

In Example 30, the memristive transistor structure of Example 29 may optionally further include that the semiconductive oxide material includes oxygen-vacancy traps for trapping oxygen vacancies to allow for a non-volatile presence of a respective memristive state defined by the spatial concentration distribution of the oxygen vacancies in the semiconductive oxide material.

In Example 31, the memristive transistor structure of any one of Examples 1 to 30 may optionally further include that the memristive material includes bismuth-iron oxide (BiFeO), preferably the memristive material includes n-type bismuth-iron oxide.

Example 32 is an electronic circuit including: a memristive circuit including a first memristive transistor structure in accordance with any one of Examples 1 to 31 and a second memristive transistor structure (preferably in accordance with any one of Examples 1 to 31) coupled to the first memristive transistor structure; and a control circuit configured to supply one or more input signals to the memristive circuit and to output one or more output signals from the memristive circuit, wherein the one or more output signals are a function of a response of the memristive circuit caused by the one or more input signals.

In Example 33 the electronic circuit of Example 32 may optionally further include that at least one of the electrodes of the first memristive transistor structure is conductively connected to at least one of the electrodes of the second memristive transistor structure.

In Example 34 the electronic circuit of Example 32 and/or 33 may optionally further include that the first memristive transistor structure and the second memristive transistor structure are coupled to one another in a series connection.

In Example 35 the electronic circuit of Example 32 and/or 33 may optionally further include that the first memristive transistor structure and the second memristive transistor structure are coupled to one another in a parallel connection.

In Example 36 the electronic circuit of any one of Examples 32 to 35 may optionally further include that at least one of the one or more gate electrodes of the first memristive transistor structure are conductively connected to at least one of the one or more gate electrodes of the second memristive transistor structure.

In Example 37 the electronic circuit of any one of Examples 32 to 36 may optionally further include that one of the at least two source/drain electrodes of the first memristive transistor structure is conductively connected to one of the at least two source/drain electrodes of the second memristive transistor structure.

In Example 38 the electronic circuit of any one of Examples 32 to 37 may optionally further include that one of the at least two source/drain electrodes of the first memristive transistor structure is conductively connected to one of the one or more gate electrodes of the second memristive transistor structure.

In Example 39 the electronic circuit of any one of Examples 32 to 38 may optionally further include that one of the at least two source/drain electrodes of the first memristive transistor structure is conductively connected to one of the at least two source/drain electrodes of the second memristive transistor structure and to one of the one or more gate electrodes of the second memristive transistor structure.

In Example 40 the electronic circuit of any one of Examples 32 to 39 may optionally further include that the control circuit is configured to supply a first input signal to the first memristive transistor structure of the memristive circuit and a second input signal to the second memristive transistor structure of the memristive circuit.

In Example 41 the electronic circuit of any one of Examples 32 to 40 may optionally further include that the control circuit is configured to supply a same input signal to both the first memristive transistor structure and the second memristive transistor structure.

In Example 42 the electronic circuit of any one of Examples 32 to 41 may optionally further include that the control circuit is configured to supply a first input signal to at least one of the one or more gate electrodes of the first memristive transistor structure and a second input signal to at least one of the one or more gate electrodes of the second memristive transistor structure.

In Example 43 the electronic circuit of any one of Examples 32 to 42 may optionally further include that the control circuit is configured to supply a same input signal to both at least one of the one or more gate electrodes of the first memristive transistor structure and at least one of the one or more gate electrodes of the second memristive transistor structure.

In Example 44 the electronic circuit of any one of Examples 32 to 43 may optionally further include that the control circuit is configured to supply an input signal at least one of the one or more gate electrodes of the first memristive transistor structure and wherein at least one of the one or more gate electrodes of the second memristive transistor structure is coupled to one of the at least two source/drain electrodes of the first memristive transistor structure.

In Example 45 the electronic circuit of any one of Examples 32 to 43 may optionally further include that the control circuit is configured to supply an input signal to at least one of the one or more gate electrodes of the second memristive transistor structure and wherein at least one of the one or more gate electrodes of the first memristive transistor structure is coupled to one of the at least two source/drain electrodes of the second memristive transistor structure.

In Example 46 the electronic circuit of any one of Examples 32 to 45 may optionally further include that the control circuit is configured to supply a first supply voltage to one of the at least two source/drain electrodes of the first memristive transistor structure and a second supply voltage different from the first supply voltage to one of the at least two source/drain electrodes of the second memristive transistor structure.

In Example 47 the electronic circuit of any one of Examples 32 to 46 may optionally further include that the control circuit is configured to tap at least one of the one or more output signals from a node between one of the at least two source/drain electrodes of the first memristive transistor structure and one of the at least two source/drain electrodes of the second memristive transistor structure.

In Example 48 the electronic circuit of any one of Examples 32 to 47 may optionally further include that the memristive circuit is configured as an inverter circuit for inverting the one or more input signals to provide the one or more output signals.

In Example 49 the electronic circuit of any one of Examples 32 to 47 may optionally further include that the memristive circuit is configured as a logic circuit for converting the one or more input signals to one or more output signals in accordance with a logic function.

According to various aspects, the memristive transistor structure as described herein may be understood as a reconfigurable (e.g., state programmable) transistor. Therefore, in some aspects, the Examples 1 to 49 are related to a reconfigurable transistor as described in Example 50.

Example 50 is a reconfigurable memristive transistor (100) including: a channel portion (110) that includes a semiconductive memristive material (110m) in configured in a first memristive operation state; a set of electrodes; and a control circuit (200) configured to operate the reconfigurable memristive transistor (100) in the first memristive operation state; to reconfigure the first memristive operation state to a second memristive operation state different from the first memristive operation state; and to operate the reconfigurable memristive transistor (100) in the second memristive operation state.

Example 51 is a method for operating a memristive transistor structure (e.g., a reconfigurable memristive transistor) including: configuring (e.g., set or reconfigure) a memristive material of a channel portion of the memristive transistor structure to bring the memristive material of the channel portion into a predefined memristive state and thereby to bring the memristive transistor structure into a predefined operation state; and operating the memristive transistor structure in the predefined operation state via one or more operation signals and one or more electrodes to control a current flow through the channel portion of the memristive transistor structure.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memristive transistor structure comprising:
a channel portion comprising a semiconductive memristive material in a predefined memristive operation state;
at least two source/drain electrodes associated with the channel portion and configured to provide an electric current path between the at least two source/drain electrodes through the channel portion; and
one or more gate electrodes associated with the channel portion and configured to change an electronic behavior of the channel portion.

2. The memristive transistor structure of claim 1,
wherein the change of the electronic behavior of the channel portion during an operation of the memristive transistor structure is associated with a change in a resistance of the channel portion.

3. The memristive transistor structure of claim 1, further comprising:
a control circuit configured to supply one or more configuration signals to at least one of the at least two source/drain electrodes, to the one or more gate electrodes to modify a memristive state of the channel portion, or both during a configuration operation to set the predefined memristive operation state.

4. The memristive transistor structure of claim 3, wherein:
the control circuit is further configured to provide the one or more configuration signals to cause a voltage drop over at least two of the gate electrodes; or
the control circuit is further configured to provide the one or more configuration signals to cause a voltage drop over one of the at least two source/drains electrodes and one or more gate electrodes; or
the control circuit is further configured to provide the one or more configuration signals to cause a voltage drop over the at least two source/drains electrodes while the memristive material of the channel portion is in a high resistive state.

5. The memristive transistor structure of claim 1,
wherein the memristive material is n-type doped or p-type doped.

6. The memristive transistor structure of claim 1,
wherein the channel portion and one or more gate electrodes are configured as a metal-semiconductor field-effect transistor structure; and/or
wherein the channel portion and one or more gate electrodes are configured as a metal-insulator-semiconductor field-effect transistor structure.

7. The memristive transistor structure of claim 1,
wherein the semiconductive memristive material is configured to selectively form at least one Schottky-Barrier in the memristive material of the channel portion as a function of a write signal to change the memristive state of the memristive material.

8. The memristive transistor structure of claim 1,
wherein the memristive material is configured to allow for a change in a spatial dopant distribution in the channel portion as a function of one or more electric signals applied to one or more gate electrodes and/or to at least one of the at least two source/drain electrodes.

9. The memristive transistor structure of claim 1,
wherein the one or more gate electrodes comprises a first gate electrode and a second gate electrode;
wherein at least a part of the channel portion is disposed between the first gate electrode and the second gate electrode; and
wherein the semiconductive memristive material is configured to allow for a change in a spatial dopant distribution in the channel portion to selectively form or modify:
I) a Schottky-Barrier between the channel portion and the first gate electrode; and/or
II) a Schottky-Barrier between the channel portion and the second gate electrode.

10. The memristive transistor structure of claim 1,
wherein the semiconductive memristive material is configured to be changed from a first memristive state to a second memristive state, wherein a dopant distribution associated with the first memristive state is different from a dopant distribution associated with the second memristive state.

11. The memristive transistor structure of claim 10,
wherein the semiconductive memristive material is configured such that the change from the first memristive state to the second memristive state is associated with a drift of ions or ion-vacancies in the semiconductive memristive material of the channel portion.

12. The memristive transistor structure of claim 10,
wherein the dopant distribution is an ion-distribution or an ion-vacancy distribution in the semiconductive memristive material of the channel portion.

13. The memristive transistor structure of claim 1,
wherein the semiconductive memristive material comprises traps for trapping ions or ion-vacancies to allow for a non-volatile presence of a respective memristive state defined by the spatial concentration distribution of the ions or ion-vacancies in the semiconductive memristive material of the channel portion.

14. The memristive transistor structure of claim 1,
wherein the semiconductive oxide material comprises oxygen vacancies and a gradient in a spatial concentration distribution of the oxygen vacancies in the semiconductive oxide material.

15. An electronic circuit comprising:
a memristive circuit comprising:
a first memristive transistor structure as claimed in claim 1; and
a second memristive transistor structure as claimed in claim 1, wherein the second memristive transistor is coupled to the first memristive transistor structure; and
a control circuit configured to supply one or more input signals to the memristive circuit and to output one or more output signals from the memristive circuit, wherein the one or more output signals are based on the one or more input signals to the memristive circuit.

16. The electronic circuit of claim 15,
wherein one or more of the electrodes of the first memristive transistor structure is conductively connected to one or more of the electrodes of the second memristive transistor structure.

17. The electronic circuit of claim 15,
wherein the first memristive transistor structure and the second memristive transistor structure are coupled to one another in a series connection or in a parallel connection.

18. The electronic circuit of claim 15,
wherein one or more gate electrodes of the first memristive transistor structure are conductively connected to one or more gate electrodes of the second memristive transistor structure; and/or
wherein one of the at least two source/drain electrodes of the first memristive transistor structure is conductively connected to one of the at least two source/drain electrodes of the second memristive transistor structure; and/or
wherein one of the at least two source/drain electrodes of the first memristive transistor structure is conductively connected to one or more gate electrodes of the second memristive transistor structure; and/or
wherein one of the at least two source/drain electrodes of the first memristive transistor structure is conductively connected to one of the at least two source/drain electrodes of the second memristive transistor structure and to one or more gate electrodes of the second memristive transistor structure.

19. The electronic circuit of claim 15,
wherein the memristive circuit is configured as an inverter circuit for inverting the one or more input signals to provide the one or more output signals; or
wherein the memristive circuit is configured as a logic circuit for converting the one or more input signals to one or more output signals in accordance with a logic function.

20. A method for operating a memristive transistor structure, the method comprising:
configuring a memristive material of a channel portion of the memristive transistor structure to bring the memristive material into a predefined memristive state and the memristive transistor structure into a predefined operation state; and
operating the memristive transistor structure in the predefined operation state via one or more operation signals and one or more electrodes to control a current flow through the channel portion of the memristive transistor structure.
